(19) United States
(12) Patent Application Publication
(10) Pub. No.: US 2013/0183777 A1
(43) Pub. Date: Jul. 18, 2013

(54) METHOD OF FORMING PHOSPHOR LAYER ON LIGHT-EMITTING DEVICE CHIP WAFER USING WAFER LEVEL MOLD

(71) Applicant: Samsung Electronics Co., Ltd., Suwon-si (KR)

(72) Inventor: Taeg-ki LIM, Hwaseong-si (KR)

(73) Assignee: SAMSUNG ELECTRONICS CO., LTD., Suwon-si (KR)

(21) Appl. No.: 13/673,453

(22) Filed: Nov. 9, 2012

(30) Foreign Application Priority Data
Jan. 12, 2012 (KR) 10-2012-0003858

(51) Int. Cl. H01L 33/50

(52) U.S. Cl. CPC H01L 33/505
USPC 438/27

(57) ABSTRACT

A method of forming a phosphor layer of light-emitting device chip wafer by using a wafer level mold includes clamping a wafer having a plurality of light-emitting device chips between a lower mold and an upper mold to form a space between the wafer and the upper mold, forming a phosphor layer on the wafer by injecting a phosphor liquid into the space, and releasing the wafer from the lower mold and the upper mold.

### CROSS-REFERENCE TO RELATED APPLICATIONS

This application claims the benefit of Korean Patent Application No. 10-2012-0003858, filed on Jan.12, 2012, in the Korean Intellectual Property Office, the disclosure of which is incorporated herein in its entirety by reference.

### BACKGROUND

1. Field

The present disclosure relates to a method of forming a phosphor layer on a wafer on which a plurality of light-emitting device chips are formed by using a wafer level mold.

2. Description of the Related Art

Light-emitting device chips, for example, light-emitting diodes (LEDs), are semiconductor devices that emit various colors of light via a light source implemented by a PN junction of a compound semiconductor. LEDs have various advantages such as long lifetime, small size, and light weight, and operating at a low driving voltage due to a strong directionality of light. LEDs have strong resistance against impact and vibrations, and do not require a preheating time and a complicated driving. LEDs are also packaged in various types, so they may be applied in various equipments.

When LEDs are manufactured by using a semiconductor manufacturing process, a plurality of LED chips are formed on a wafer in order to obtain high productivity.

Conventionally, in order to form phosphor layers on light-emitting device chips at a wafer level, after forming a thick photoresist pattern on a wafer, the phosphor layer is screen-printed on the thick photoresist pattern. After the phosphor layer is lapped on a wafer level with a desired thickness, the thick photoresist pattern is then removed.

In the conventional method, phosphor layers having same thickness may be formed on light-emitting device chips at a wafer level, which may downgrade the light emitting quality of the light-emitting devices. It is desirable that the thicknesses of the phosphor layers vary to achieve proper light-emitting characteristics of each of the light-emitting device chips.

### SUMMARY

An aspect of the disclosure encompasses methods of manufacturing phosphor layers on a light-emitting device chip wafer by using a wafer level mold such that the phosphor layers have a thickness corresponding to the height of each of the light-emitting device chips at wafer level.

Since the heights of the phosphor layers are determined in consideration of the characteristics of each of the light-emitting device chips, color realizations of manufactured light-emitting device chips having the phosphor layers thereon at a wafer level may be uniform, thereby making it possible to improve the quality of a package that uses the light-emitting device chips.

Another aspect of the disclosure relates to a method of forming a phosphor layer of a light-emitting device chip. The method includes clamping a wafer having a plurality of light-emitting device chips between a lower mold and an upper mold to form a space between the wafer and the upper mold; forming a phosphor layer on the wafer by injecting a phosphor liquid into the space; and releasing the wafer from the lower mold and the upper mold.

The clamping of the wafer may include covering upper surfaces of electrodes of the light-emitting device chips with a plurality of rods on a ceiling of the upper mold.

The method may further include forming a release layer on the upper mold before the clamping of the wafer, wherein the release layer facilitates the releasing of the wafer.

The method may further include measuring a peak wavelength emitted from each of the light-emitting device chips of the light-emitting device chip wafer; and adjusting the upper mold having distances from a ceiling of the upper mold to corresponding upper surface of the light-emitting device chips according to the peak wavelength of the light-emitting device chips.

The distances from the ceiling of the upper mold to the upper surfaces of the light-emitting device chips are reduced as the peak wavelength of the light-emitting device chip becomes larger.

Still another aspect of the disclosure provides a method of forming a phosphor layer of a light-emitting device chip wafer by using a wafer level mold. The method includes measuring peak wavelengths emitted from each of light-emitting device chips formed on a wafer; mounting the wafer on a lower mold; clamping an upper mold to the lower mold to form a space between the wafer and the upper mold; forming a phosphor layer on the wafer by injecting a phosphor liquid into the space; and releasing the wafer from the lower mold and the upper mold. Distances from upper surfaces of the light-emitting device chips to a ceiling of the upper mold are adjusted according to the peak wavelength of the light-emitting device chips.

Another aspect of the disclosure encompasses a molding device for molding a phosphor layer on a light-emitting device chip wafer having a plurality of light-emitting chips. Each of the plurality of light-emitting chips has a substrate, a light emitting structure emitting a light disposed on the substrate, and an electrode disposed on the light-emitting structure. The molding device comprises a lower mold having a groove in which the light-emitting device chip wafer is disposed, and an upper mold having a rim on its peripheral extending in a direction to the lower mold, and a plurality of rods extending in the direction to the lower mold from an inside ceiling of the upper mold. Each of the plurality of rods covering the electrode in each of the plurality of light-emitting chips. The lower mold or the upper mold has a phosphor injection hole through which a phosphor liquid is injected.

The present disclosure improves productivity since the phosphor layer is formed at a wafer level. An additional lapping process is unnecessary after forming the phosphor layer, and manufacturing process is simple because a thick photoresist is not used. Since the height of the phosphor layer is determined in consideration of characteristics of each of the light-emitting device chips, quality of a light-emitting device package that uses the manufactured light-emitting device chips may be improved.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic cross-sectional view of an exemplary light-emitting device chip according to an embodiment of the present disclosure;

FIGS. 2A through 2F are drawings for showing a method of manufacturing phosphor layers on a light-emitting device chip wafer using a wafer level mold according to an embodiment of the present disclosure; and

FIG. 3 is a graph showing measuring results of peak wavelength of light-emitting device chips in a diametric direction across the wafer.

### DETAILED DESCRIPTION

Reference will now be made in detail to embodiments, examples of which are illustrated in the accompanying drawings. In the drawings, like reference numerals refer to like elements throughout and the size and thickness of each element may be exaggerated for clarity and convenience of explanation. It will also be understood that when a layer is referred to as being “on” or “above” another layer or substrate, it can be directly on the other layer or substrate, or intervening layers may also be present.

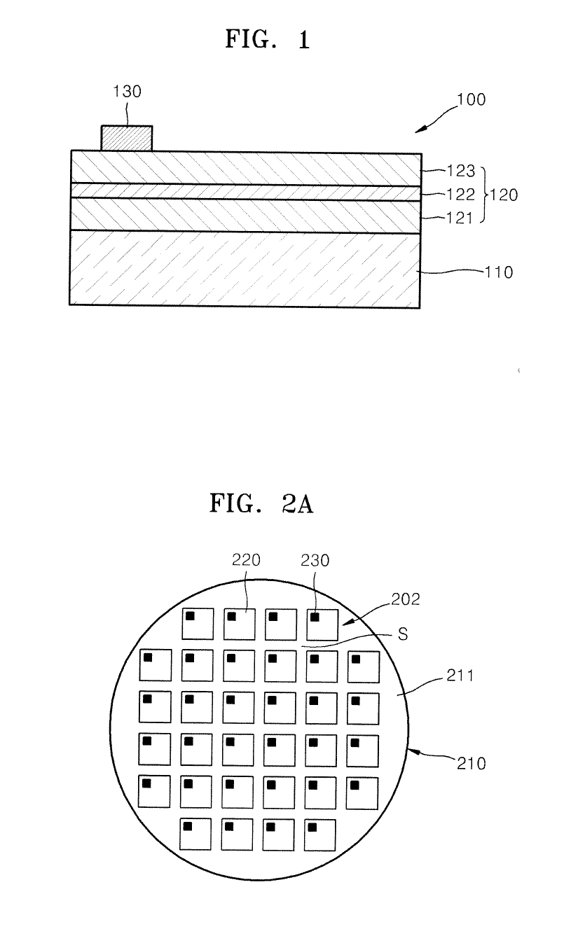

FIG. 1 is a schematic cross-sectional view of an exemplary light-emitting device chip 100 according to an embodiment of the present disclosure.

Referring to FIG. 1, a light-emitting structure 120 for light-emitting is formed on a substrate 110, for example, a silicon aluminum (SiAl) substrate. The light-emitting structure 120 may include a first nitride layer 121, an active layer 122, a second nitride layer 123 sequentially stacked on the substrate 110. The first nitride layer 121 and the second nitride layer 123 may be doped with either one of a p-type dopant and an n-type dopant respectively, of which dopants are different from each other. In the current embodiment, the first nitride layer 121 is an n-type nitride layer and the second nitride layer 123 is a p-type nitride layer. The first nitride layer 121 may be formed of InₓGa_{y}Al_{z}N. The first nitride layer 121 may be a single layer formed of a single composition or multiple layers having different compositions.

The active layer 122 may be a plurality of active layers having a quantum well layer structure in which GaN and InGaN are alternately formed.

The second nitride layer 123 may be formed of InₓGa_{y}Al_{z}N. The second nitride layer 123 may be a single layer formed of a single composition or multiple layers having different compositions.

A first electrode 130 is formed on the second nitride layer 123. The first electrode 130 may be a p-type electrode. The substrate 110 formed of SiAI may function as an n-type electrode.

In FIG. 1, the light-emitting device chip 100 having a vertical type electrode structure is shown. However, the light-emitting device chip according to the present disclosure is not limited thereto. For example, the light-emitting device chip 100 may have a horizontal type electrode structure, and the description thereof is omitted.

On a wafer on which a plurality of light-emitting device chips are formed, a phosphor layer may be formed on a region of the light-emitting device chip except a region of an electrode, for example, the first electrode 130 of FIG. 1, in order to form the phosphor layer at a wafer level on each of the light-emitting device chips.

A phosphor layer may be formed by covering the first electrode 130 with a thick photoresist pattern. This method is complicated because it requires a process of removing the thick photoresist pattern and a process of lapping for controlling the height of the phosphor layer.

Hereinafter, a method of forming a phosphor layer at a wafer level on light-emitting device chips is described.

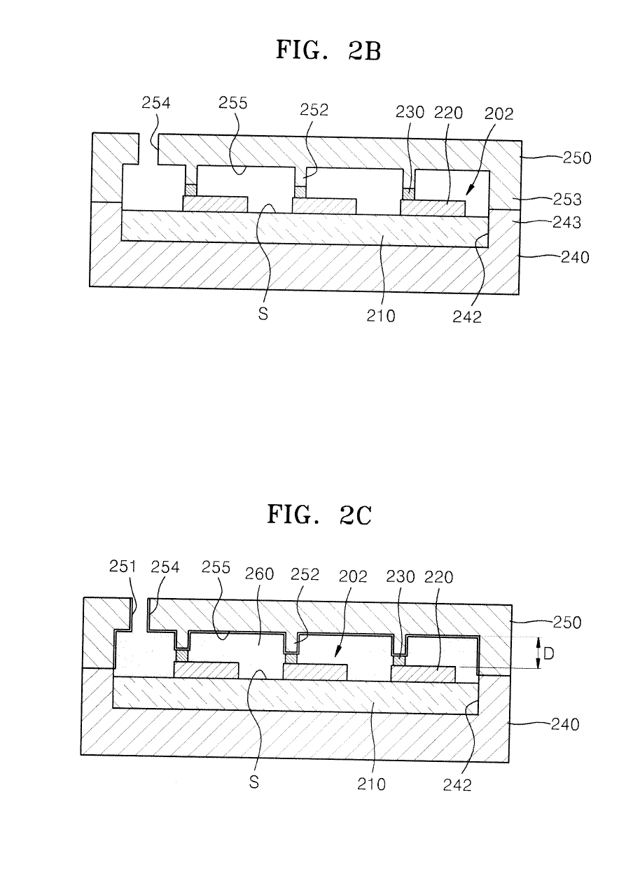

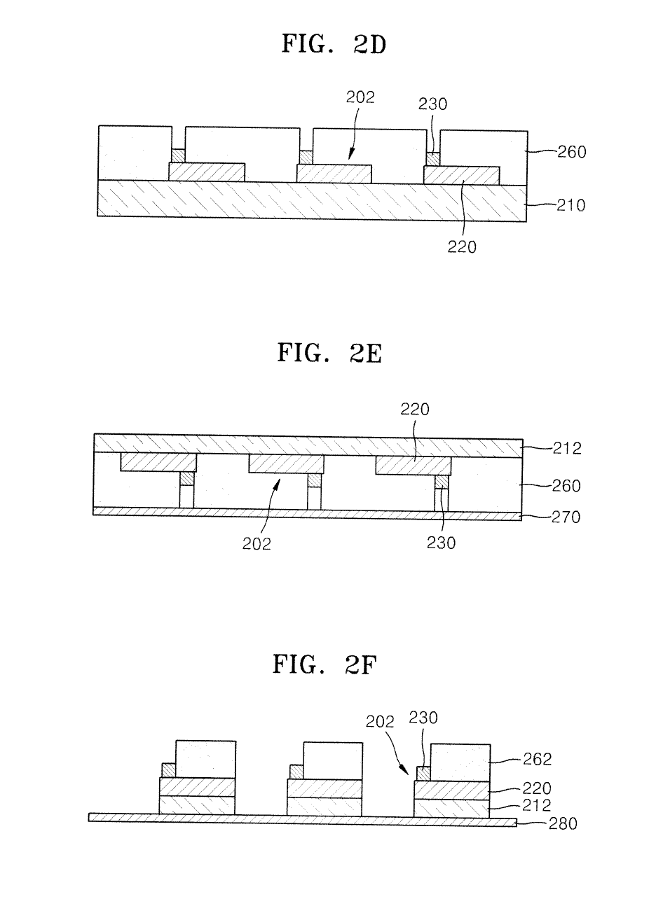

FIGS. 2A through 2F are drawings for showing a method of manufacturing phosphor layers on a light-emitting device chip wafer using a wafer level mold according to an embodiment of the present disclosure. Like reference numerals are used to indicate elements that are substantially identical to the elements of the light-emitting device chip 100 of FIG. 1, and the descriptions thereof are omitted.

Referring to FIG. 2A, a plurality of light-emitting device chips 202 are formed on an upper surface 211 of a single wafer 210. In FIG. 2A, a few tens of light-emitting device chips 202 are formed on the single wafer 210. However, practically, a few thousands of light-emitting device chips 202 may be formed on the single wafer 210. The light-emitting device chips 202 may be substantially the same as the light-emitting device chip 100 of FIG. 1.

The wafer 210 may be formed of SiAl, and the GaN group semiconductor, 220 are formed on the wafer 210. First electrodes 230 are formed on the GaN group semiconductor layers 220. The light-emitting device chips 202 may be formed in a matrix array. Also, the light-emitting device chips 202 may have various structures, and for example, may have the structure of the vertical type light-emitting device chip 100 of FIG. 1. The GaN group semiconductor layers 220, and the first electrodes 230 correspond to the semiconductor layer 120, and the first electrode 130 of FIG. 1, respectively.

Referring to FIG. 2B, a lower mold 240 and an upper mold 250 are prepared to dispose the wafer 210 therebetween. The lower mold 240 includes a mounting groove 242, in which the wafer 210 is mounted, and a rim 243 that surrounds the wafer 210. The upper mold 250 includes a rim 253 corresponding to the rim 243 of the lower mold 240. The rim 253 of the upper 250 and the rim 243 of the lower mold 240 support and face each other. A predetermined space 202 is formed between the upper mold 250 and the wafer 210, in which a phosphor liquid is injected.

The upper mold 250 includes a plurality of rods 252 which extend from a ceiling 255 of the upper mold 250 to the first electrodes 230 of the light-emitting device chips 202. Each of the rods 252 covers an upper surface of the first electrode 230, and may cover the entire upper surface of the first electrode 230 to prevent the first electrode 230 from being coated by a phosphor layer in a subsequent phosphor layer coating process.

A phosphor liquid injection hole 254 for injecting a phosphor liquid is formed in the upper mold 250 or the lower mold 240. In FIG. 2B, the phosphor liquid injection hole 254 is formed in the upper mold 250. However, the present disclosure is not limited thereto, and for example, the phosphor liquid injection hole 254 may be formed in the lower mold 240.

The upper mold 250 and the lower mold 240 may be formed of an ordinary metal, such as iron or aluminum.

Referring back to FIG. 2B, the wafer 210 is mounted on the mounting groove 242 of the lower mold 240. The wafer 210 is disposed to contact the mounting groove 242. Next, the upper mold 250 and the lower mold 240 are clamped so that the rods 252 cover the first electrodes 230 of the light-emitting device chips 202.

In FIG. 2B, for convenience of explanation, three light-emitting device chips and an upper mold and a lower mold corresponding to the three light-emitting device chips are depicted. However, practically, a wafer having more than three light-emitting device chips, for example, a few thousands of light-emitting device chips may be disposed between the upper mold and the lower mold.

Referring to FIG. 2C, a phosphor layer 260 is formed on the light-emitting device chips 202 by supplying a phosphor liquid through the phosphor liquid injection hole 254 formed on the upper mold 250. That is, the phosphor liquid is supplied into the space between the upper mold 250 and the wafer 210. The phosphor liquid may be a liquid including a silicon resin or an epoxy resin in which phosphor particles are distributed. For a light-emitting device that emits white light, the light-emitting device chip may be a light-emitting device chip that emits blue light, and the phosphor particles may be a yellow phosphor, or a phosphor of a mixture of a red phosphor and a green phosphor.

The phosphor liquid injected through the phosphor liquid injection hole 254 covers each of the light-emitting device chips 202 in the space between the upper mold 250 and the wafer 210 except regions, where electrodes 230 occupies, by flowing between the rods 252. The phosphor layer 260 also fills a region between the light-emitting device chips 202, that is, a street S shown in FIG. 2A.

A distance D between the upper surface of the light-emitting device chip 202 and the ceiling 255 of the upper mold 250 corresponds to a thickness of the phosphor layer 260 on the light-emitting device chip 202. The thickness of the phosphor layer 260 may be approximately 70 um. However, an appropriate thickness of the phosphor layer 260 may vary depending upon a peak wavelength of the light-emitting device chip 202.

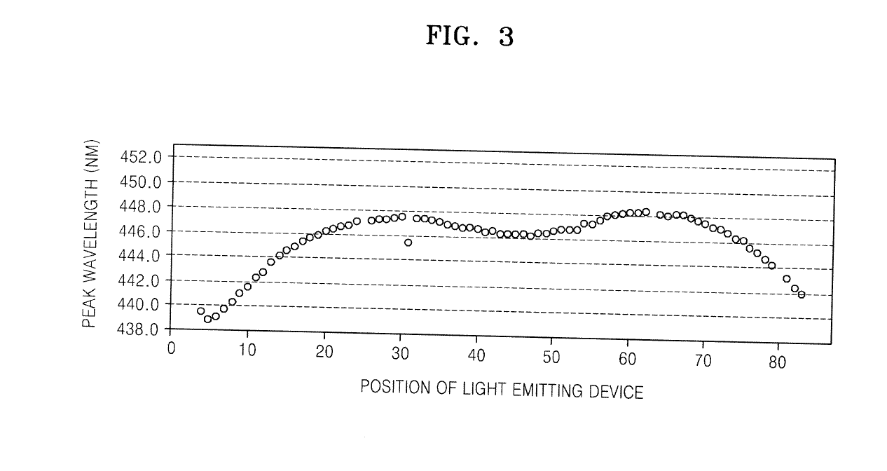

FIG. 3 is a graph showing peak wavelengths of light-emitting device chips 202 in a diametrical direction across the center of the wafer 210. Referring to FIG. 3, the peak wavelength of the light-emitting device chips 202 is approximately from about 438.9 nm to about 448.4 nm. The peak wavelength of the light-emitting device chips 202 varies according to location thereof. In a region where the peak wavelength is relatively high, the phosphor layer 260 may have a relatively small thickness, and in a region where the peak wavelength is relatively low, the phosphor layer 260 may have a relatively large thickness. For this purpose, the distance D between the upper surface of the light-emitting device chip 202 and the ceiling 255 of the upper mold 250 is controlled in advance. For example, if the peak wavelength is relatively high, e.g. 3 nm, the distance D may be reduced to approximately from about 1 μm to about 20 μm.

In general, the light-emission characteristics of light-emitting device chips on a wafer may uniformly vary according to their positions in same batch process. Also, because the light-emission characteristics of light-emitting device chips at a concentric position on a wafer are similar to each other, instead of measuring the light-emission characteristics of each of the light-emitting device chips on a wafer, the light-emission characteristics of the light-emitting device chips in the diametric direction may be applied to the light-emitting device chips at the corresponding concentric position, after measuring the light-emission characteristics of light-emitting device chips in a diametric direction,. The measurement of peak wavelength of the light-emitting device chips on each wafer is unnecessary at the same batch process. Accordingly, the distance D in the upper mold 250 may be formed in a predetermined pattern according to a batch process.

A release layer 251, for example, a Teflon coating, may be formed on the upper mold 250. The release layer 251 may facilitate the release of the wafer 210, on which the phosphor layer 260 is formed, from the upper mold 250. Also, the release layer 251 may protect the first electrodes 230, when the rods 252 contact the first electrodes 230.

Referring to FIG. 2D, the wafer 210 are separated from the lower mold 240 and the upper mold 250. The phosphor layer 260 is formed on the wafer 200, and is not formed on the first electrodes 230 of the light-emitting device chips.

Referring to FIG. 2E, a protection tape 270 is attached on the wafer 210. The protection tape 270 provides a surface for fixing the wafer 210 while protecting the phosphor layer 260. Next, a lower surface of the wafer 210 may be ground using a grinder (not shown) to obtain a desired thickness of the wafer 210. For example, the wafer 210 having a thickness of 500 pm may be ground to obtain a thickness of 150 pm of the wafer 212. Next, the protection tape 270 is removed.

Referring to FIG. 2F, after placing the wafer 212 on a dicing tape 280, light-emitting device chips 202 are separated by dicing the wafer 212. In the dicing process, the phosphor layer 260 between the light-emitting device chips 202 is removed, and thus, a phosphor layer 262 remains only on each of the light-emitting device chips 202. The dicing tape 280 may be any adhesive tape, and thus, is not specifically defined. For example, the dicing tape 280 may be an ultraviolet tape (UV tape) or a thermosetting tape. The dicing tape 280 may have a thickness of from about 50 μm to about 200 μm.

The separated light-emitting device chips 202 are used to manufacture light-emitting device packages through a packaging process, and the description thereof is omitted.

In the current embodiment, a vertical type light-emitting device chip is described. However, the present invention is not limited thereto. For example, if a p-type electrode and an n-type electrode are formed on a GaN semiconductor layer, two rods corresponding to two electrodes of each of the light-emitting device chips may be formed on the upper mold, and thus, the two electrodes may be covered when a phosphor liquid is injected. This description is omitted.

While the present disclosure has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming a phosphor layer of a light-emitting device chip wafer, the method comprising steps of:
clamping a wafer having a plurality of light-emitting device chips between a lower mold and an upper mold to form a space between the wafer and the upper mold;
forming a phosphor layer on the wafer by injecting a phosphor liquid into the space; and
detaching the wafer from the lower mold and the upper mold.

2. The method of claim 1, wherein the step of clamping of the wafer comprises covering electrodes of the light-emitting device chips with a plurality of rods extending from a ceiling of the upper mold.

3. The method of claim 2, further comprising forming a release layer on the upper mold before the clamping of the wafer, wherein the release layer facilitates the detachment of the wafer in the step of detaching the wafer.

4. The method of claim 2, further comprising steps of:
measuring a peak wavelength emitted from each of the light-emitting device chips of the light-emitting device chip wafer; and
adjusting distances from a ceiling of the upper mold to the corresponding upper surface of the light-emitting device chips according to the peak wavelength of the light-emitting device chips.

5. The method of claim 4, wherein the distances are reduced as the peak wavelength of the light-emitting device chip becomes larger.

6. The method of claim 2, wherein the covering electrodes of the light-emitting device chips covers entire upper surfaces of the electrodes.

7. The method of claim 1, further comprising steps of:
attaching a protection tape to the formed phosphor layer;
grinding a lower surface of the wafer to obtain a desired thickness of the wafer;
removing the protection tape;
placing the wafer on a dicing tape;
removing the phosphor layer between the plurality of semiconductor chips; and
separating the dicing tape from the wafer.

8. A method of forming a phosphor layer of a light-emitting device chip wafer by using a wafer level mold, the method comprising:
measuring peak wavelengths emitted from each of light-emitting device chips formed on a wafer;
mounting the wafer on a lower mold;
clamping an upper mold to the lower mold to form a space between the wafer and the upper mold;
forming a phosphor layer on the wafer by injecting a phosphor liquid into the space; and
releasing the wafer from the lower mold and the upper mold,
wherein distances from upper surfaces of the light-emitting device chips to a ceiling of the upper mold are adjusted according to the peak wavelength of the light-emitting device chips.

9. The method of claim 8, wherein the clamping comprises covering electrodes of the light-emitting device chips using a plurality of rods extending from a ceiling of the upper mold facing the lower mold.

10. The method of claim 8, further comprising forming a release layer on the upper mold before the clamping, wherein the release layer facilitates the release of the upper mold from the wafer in the step of releasing.

11. The method of claim 8, wherein the distances are reduced as the peak wavelength of the light-emitting device chip becomes larger.
